(19) United States
(12) Patent Application Publication
(10) Pub. No.: US 2012/0068745 A1
(43) Pub. Date: Mar. 22, 2012

(54) INJECTION-LOCKED FREQUENCY DIVIDER

(75) Inventors: Hsieh-Hung HSIEH, Taipei City (TW); Chewn-Pu JOU, Chutung (TW); Fu-Lung HSUEH, Cranbury, NJ (US)

(73) Assignee: Taiwan Semiconductor Manufacturing Co., Ltd., Hsin-Chu (TW)

(21) Appl. No.: 12/887,984

(22) Filed: Sep. 22, 2010

(51) Int. Cl. H03L 7/08; H03B 19/12

(52) U.S. Cl. 327/157; 327/118

(57) ABSTRACT

A representative injection-locked frequency divider includes a differential direct injection pair that is configured to receive and mix differential injection signals and an oscillator that is electrically connected to the differential direct injection pair and produces an operating frequency based on the mixed differential injection signals.

### TECHNICAL FIELD

The present invention relates to electrical circuits, and more particularly to injection-locked frequency dividers.

### BACKGROUND

Millimeter-wave frequency typically refers to the frequency band between 30 and 300 GHz. Within this frequency range, the wavelength of electromagnetic signals is small. Since the device size of passive component is usually in proportion to the wavelength, the passive element at millimeter-wave frequencies becomes reduced, making the integration more effective. Currently, some millimeter-wave applications include the wireless personal area network at 60 GHz, automotive radar at 77 GHz, and image sensing at 90 GHz.

A millimeter-wave frequency divider is typically included in a high-frequency phase-locked loop. Due to the high-speed capability and low-power characteristics, the injection-locked frequency divider is well suited for millimeter-wave operations. However, the division ratio (normally two) and locking range of millimeter-wave injection-locked frequency divider are inherently limited.

An injection-locked frequency divider design that would improve upon the conventional injection-locked frequency divider designs would be desirable in the art.

### SUMMARY

A representative injection-locked frequency divider includes a differential direct injection pair that is configured to receive and mix differential injection signals, and an oscillator that is electrically connected to the differential direct injection pair and produces an operating frequency based on the mixed differential injection signals.

The above and other features of the present invention will be better understood from the following detailed description of the preferred embodiments of the invention that is provided in connection with the accompanying drawings.

### BRIEF DESCRIPTION OF THE DRAWINGS

The accompanying drawings illustrate preferred embodiments of the invention, as well as other information pertinent to the disclosure, in which:

FIG. 1 is a block diagram that illustrates a high-frequency phase-locked loop circuit having an injection-locked frequency divider in accordance with an embodiment of the present disclosure;

FIG. 2 is a high-level block diagram that illustrates a divide-by-three injection-locked frequency divider in accordance with an embodiment of the present disclosure;

FIG. 3 is a more detailed block diagram that illustrates a divide-by-three injection-locked frequency divider in accordance with an embodiment of the present disclosure;

FIG. 4 is a more detailed block diagram that illustrates a divide-by-three injection-locked frequency divider in accordance with another embodiment; and

FIGS. 5 and 6 illustrate charts that show the increase of a locking range using divide-by-three injection-locked frequency dividers in accordance with the disclosed embodiments.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Exemplary systems are first discussed with reference to the figures. Although these systems are described in detail, they are provided for purposes of illustration only and various modifications are feasible.

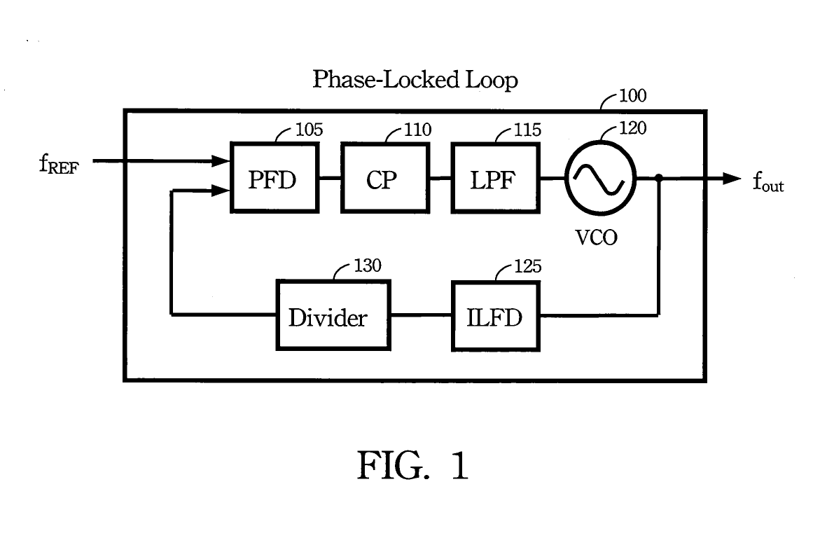

FIG. 1 is a block diagram that illustrates an embodiment of a phase-locked loop (PLL) circuit 100 having an injection-locked frequency divider (ILFD) 125. The frequency PLL circuit 100 is capable of high-frequency operation, for example including a frequency band between approximately 30 and 300 GHz. Because of the operating frequency, the high-frequency PLL circuit 100 generally includes an injection-locked frequency divider (ILFD) 125 due to its high-speed capability and low-power characteristic.

In connection with the ILFD 125, it is beneficial to consider the frequency PLL circuit 100. PLL circuits can be executed using digital or analog circuits but will be explained generally with the understanding that the ILFD 125 may be applicable to both circuit types. The phase locked loop PLL 100 can start with phase detector 105. Such phase detector 105 generally compares two input signals—at a reference frequency and a feedback frequency—and produces an error signal that is proportional to their phase difference. The error signal is sent to a charge pump 110 that supplies charge in an amount proportional to the phase error detected.

A low-pass filter 115 receives the charge-represented phase error signal and filters the received phase error signal. The filtered signal drives a voltage-controlled oscillator (VCO) 120, which creates an output frequency. Such output frequency is fed through an injection-locked frequency divider (ILFD) 125 and a divide-by-N counter 130 back into the input of the phase detector 105, in a negative feedback loop. If the output frequency of the VCO 120 drifts up or down to a greater or lesser degree, the error signal can increase or decrease accordingly, driving the VCO frequency in the opposite direction so as to reduce the error. Thus the output is locked to the reference frequency, which can be derived from a crystal oscillator or other source (not shown).

Referring now to injection-locked frequency divider (ILFD) 125, the frequency of the input signal generally is a frequency of the free-running frequency of the oscillator 120. The input signal is then divided by the ILFD 125. The divided signal from the ILFD 125 is received by a divide-by-N counter 130.

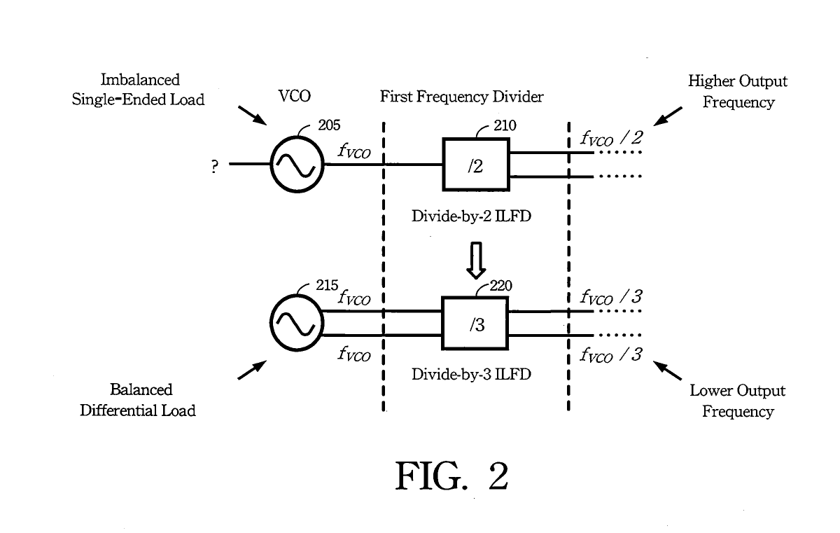

This disclosure describes an ILFD 125 designed to increase the locking range without any tuning mechanism, which is an advantage according to the invention but can be a drawback for ILFDs currently available in the industry. Other advantages and improvements of the ILFD 125 will be apparent to those skilled in the art. The ILFD 125 is further discussed in FIGS. 2-6.

The divide-by-N counter 130 receives the divided signal from the ILFD 125 and generates an integer number of the divided signal. A non-integer number of the divided signal can be created by replacing the simple divide-by-N counter in the feedback path with a programmable pulse swallowing counter.

FIG. 2 compares block diagrams of a divide-by-two injection-locked frequency divider (ILFD) 210 and a divide-by-three ILFD 220, illustrating some of their basic characteristics. The divide-by-two ILFD 210 can be used as part of the implementation of the high-frequency phase-locked loop (PLL) circuit 100. However, the divide-by-two ILFD 210 can have difficulties in generating a divided signal from the output frequency of the VCO 120 due to the higher self-oscillation frequency. Further, the divide-by-two ILFD 210 generally receives a single-ended injection load from the VCO 120, which can be difficult to balance where the VCO 120 is a differential injection signal source.

An improved embodiment compared to the divide-by-two ILFD 210 is a divide-by-three ILFD 220, which can address certain short-comings of the divide-by-two ILFD 210. One advantage, among others, of using the divide-by-three ILFD 220 is that output of the VCO 120 is applied to a balanced differential load rather than an unbalanced single-ended injection load. Also, assuming that the VCOs 205 or 215 are running at a given frequency, the divide-by-three ILFD 220 generates a lower frequency than the divide-by-two ILFD 210, which is desirable in this application. The remaining disclosure presents various designs of the divide-by-three ILFD 220 having advantageous aspects.

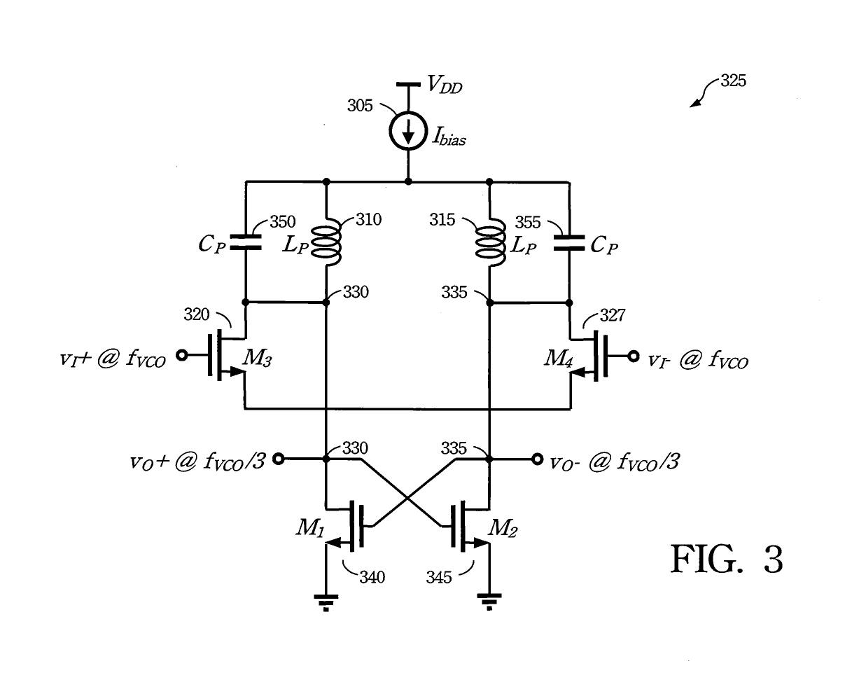

FIG. 3 is a schematic diagram that illustrates an embodiment of a divide-by-three injection-locked frequency divider (ILFD) 325, such as that shown in FIG. 2. The divide-by-three ILFD 325 receives current I_{bias} from a current source 305 that supplies the current from a voltage source V_{DD}. The divide-by-three ILFD 325 includes a differential direct injection pair 320, 327 that is configured to receive complementary or differential injection signals v_{I}+ and v_{I}− operating at a frequency of f_{vco} from the VCO 120 (FIG. 2). The differential direct injection pair 320, 327 can be implemented with NMOS-type transistors 320, 327. The differential injection signals can include RF signals operating at a frequency three times the output frequency of the divide-by-three ILFD 325. In other words, the output frequency is the complementary or differential injection signals from the VCO 120 divided by three, /3. The RF signals are generally transmitted by a signal generator, such as the VCO 120 (FIG. 1) or a differential oscillator (not shown).

The divide-by-three ILFD 325 further includes an oscillator 310, 315, 350, 355, 340, 345 that is electrically connected to the differential direct injection pair 320, 327 and produces the output frequency based on the mixed differential injection signals. The oscillator can include a resonator 310, 315, 350, 355 and a cross-coupled transistor pair 340, 345. In this example, the resonator is implemented with inductors 310, 315 and parasitic capacitors 350, 355 from the cross-coupled transistor pair 340, 345 and the differential direct injection pair 320, 327, and the cross-coupled transistor pair 340, 345 can be implemented with NMOS-type transistors 340, 345.

The differential direct injection pair 320, 327 is electrically connected to the oscillator 310, 315, 350, 355, 340, 345 in a direct-injection scheme where the differential injection signals are injected into the input of the differential direct injection pair 320, 327. The differential direct injection pair 320, 327 can operate as switches to turned on and off the divide-by-three ILFD 325.

Frequency division happens as the differential direct injection pair 320, 327 converts the complementary or differential injection signals v_{I}+ and v_{I}− into differential currents, which mixes with the cross-coupled transistor pair 340, 345. The harmonics except the fundamental frequency are filtered out by the LC tank resonator formed by inductors 310, 315 and parasitic capacitors 350, 355. The even-order nonlinearity of the cross-coupled transistor pair 340, 345 can generate the desired mixing signal that corresponds to a division ratio of any odd number. In this example, the division ratio is 3 but ratio can be 5, 7, 9, 11 or any other odd numbers.

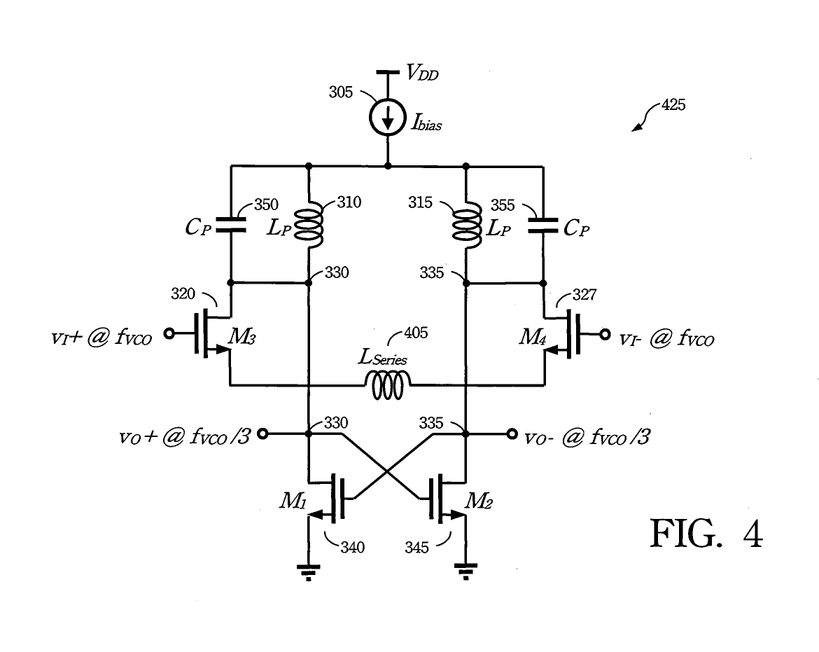

FIG. 4 is a more detailed block diagram that illustrates an embodiment of a divide-by-three injection-locked frequency divider 425, such as that shown in FIG. 2. In this example, the architecture of the divide-by-three injection-locked frequency divider 425 of FIG. 4 is similar to the architecture of the divide-by-three injection-locked frequency divider 325 as described in FIG. 3. Like features are labeled with the same reference numbers, such as the differential direct injection pair 320, 327, the oscillator 310, 315, 350, 355, 340, 345. However, the divide-by-three injection-locked frequency divider 425 further includes an inductor 405 in series with the differential direct injection pair 320, 327. The inductor 405 in series reduces parasitic capacitance that exists in the divide-by-three injection-locked frequency divider 425, thereby enhancing the locking range of the divide-by-three injection-locked frequency divider 425.

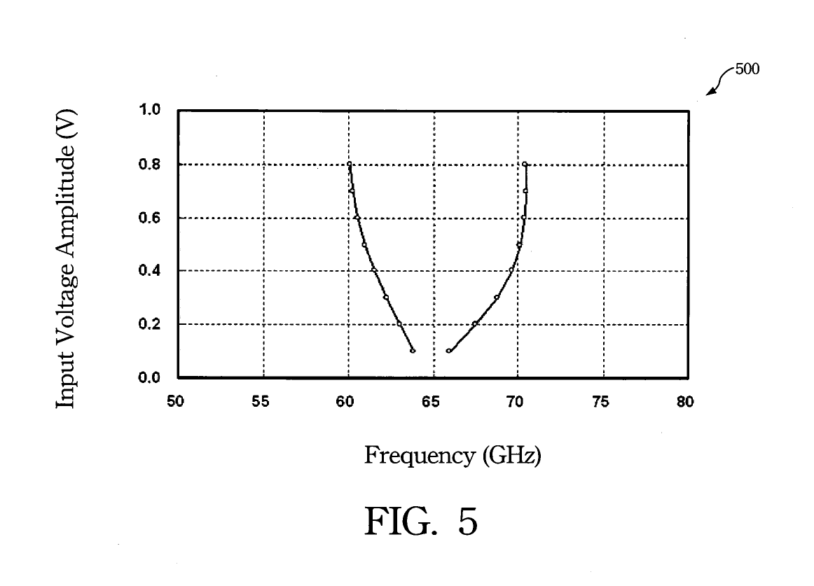

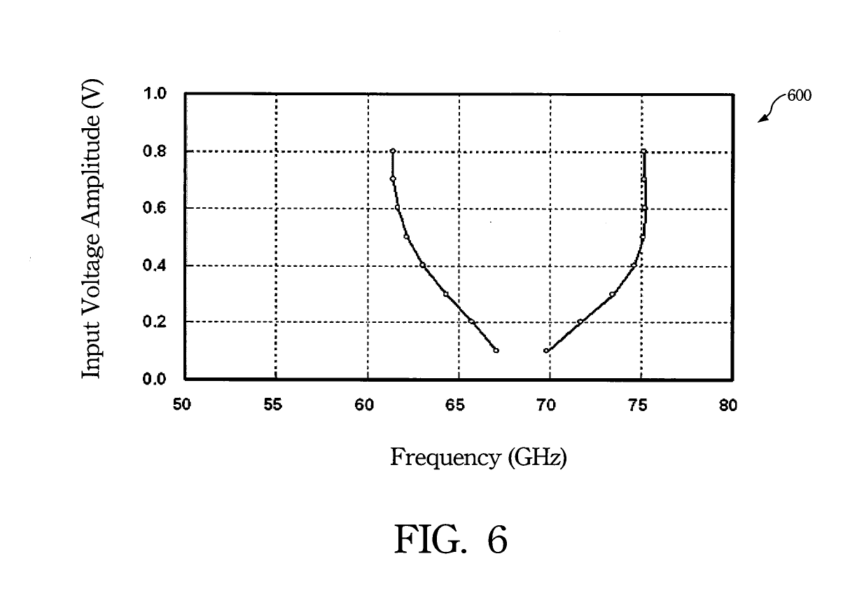

FIGS. 5 and 6 illustrate charts 500, 600 that show the increase of locking ranges using the divide-by-three injection-locked frequency dividers 325, 425, such as that shown in FIGS. 3 and 4, respectively. The charts 500, 600 are simulation results where the divide-by-three injection-locked frequency dividers 325, 425 operate at a supply voltage of 1.0 Volts and the operating frequency is in the vicinity of 70 GHz. With the input voltage amplitude of 0.6 V, the locking range for the divide-by-three injection-locked frequency divider 325 is 9.78 GHz and the locking range for the divide-by-three injection-locked frequency divider 425 is 13.60 GHz.

It should be noted that the NMOS-type transistors 320, 327, 340, 345 shown in the FIGS. 3 and 4 can be designed with PMOS-type transistor or any other kinds of transistors, as can be appreciated by those skilled in the art. Also, the ILFD 125, 220, 325, 425 and/or the phase-locked loop circuit 100 can be implemented in an integrated circuit or any other miniature electronic circuit.

Although the invention has been described in terms of exemplary embodiments, it is not limited thereto. Rather, the appended claims should be construed broadly to include other variants and embodiments of the invention that may be made by those skilled in the art without departing from the scope and range of equivalents of the invention.

What is claimed is:

1. An injection-locked frequency divider comprising:
a differential direct injection pair that is configured to receive and mix differential injection signals; and
an oscillator that is electrically connected to the differential direct injection pair and produces an operating frequency based on the mixed differential injection signals.

2. The injection-locked frequency divider of claim 1, wherein the differential direct injection pair is electrically connected to the oscillator in a direct-injection scheme.

3. The injection-locked frequency divider of claim 1, wherein the differential direct injection pair includes NMOS-type transistors or PMOS-type transistors.

4. The injection-locked frequency divider of claim 1, wherein the differential direct injection pair operates as switches to turned on and off the injection-locked frequency divider.

5. The injection-locked frequency divider of claim 1, wherein the differential injection signals include RF signals operating at a frequency three times the operating frequency, the RF signals being transmitted by a signal generator.

6. The injection-locked frequency divider of claim 5, wherein the signal generator includes at least one of the following: a second oscillator and a voltage-controlled oscillator.

7. The injection-locked frequency divider of claim 1, wherein the oscillator includes a differential oscillator or a voltage-controlled oscillator.

8. The injection-locked frequency divider of claim 1, wherein the oscillator includes a resonator and a cross-coupled transistor pair.

9. The injection-locked frequency divider of claim 1, further comprising an inductor in series with the differential direct injection pair.

10. A phase-locked loop comprising:
a phase frequency detector having an input and an output, the input of the phase frequency detector being configured to receive a reference input signal and a feedback signal and detect a phase difference between the reference input signal and the feedback signal, the phase frequency detector being configured to produce an error signal based on the phase difference at the output of the phase frequency detector;
a signal generator having an input and an output, the input of the signal generator being configured to receive the error signal from the phase frequency detector, the signal generator being configured to produce an output frequency based on the error signal at its output;
an injection-locked frequency divider (ILFD) that is electrically coupled to the output of the signal generator and receives comprising:
a differential direct injection pair that is configured to receive the output frequency from the signal generator; and
an oscillator that is electrically connected to the differential direct injection pair and produces an oscillation frequency, wherein the differential direct injection pair mixes the output frequency and the oscillation frequency to produce an ILFD output frequency; and
a frequency divider that receives the ILFD output frequency and produces the feedback signal to the input of the phase frequency detector.

11. The phase-locked loop of claim 10, wherein the differential direct injection pair is electrically connected to the oscillator in a direct-injection scheme.

12. The phase-locked loop of claim 10, wherein the differential direct injection pair includes NMOS-type transistors or PMOS-type transistors.

13. The phase-locked loop of claim 10, wherein the differential direct injection pair operates as switches to turned on and off the injection-locked frequency divider.

14. The phase-locked loop of claim 10, wherein the output frequency of the signal generator includes RF signals operating at a frequency three times the ILFD output frequency.

15. The phase-locked loop of claim 14, wherein the signal generator includes at least one of the following: a second oscillator, differential oscillator, and a voltage-controlled oscillator.

16. The phase-locked loop of claim 10, wherein the oscillator includes a resonator and a cross-coupled transistor pair.

17. The phase-locked loop of claim 16, wherein the resonator is an LC tank resonator.

18. The phase-locked loop of claim 10, wherein ILFD further comprises an inductor in series with the differential direct injection pair.

19. An integrated circuit comprising:
a phase frequency detector having an input and an output, the input of the phase frequency detector being configured to receive a reference input signal and a feedback signal and detect a phase difference between the reference input signal and the feedback signal, the phase frequency detector being configured to produce an error signal based on the phase difference at the output of the phase frequency detector;
a signal generator having an input and an output, the input of the signal generator being configured to receive the error signal from the phase frequency detector, the signal generator being configured to produce an output frequency based on the error signal at its output;
an injection-locked frequency divider (ILFD) that is electrically coupled to the output of the signal generator and receives comprising:
a differential direct injection pair that is configured to receive the output frequency from the signal generator, wherein the differential direct injection pair operates as switches to turned on and off the injection-locked frequency divider, and
an oscillator that is electrically connected to the differential direct injection pair in a direct-injection scheme and produces an oscillation frequency, wherein the differential direct injection pair mixes the output frequency and the oscillation frequency to produce an ILFD output frequency; and
a frequency divider that receives the ILFD output frequency and produces the feedback signal to the input of the phase frequency detector.

20. The integrated circuit of claim 19, wherein the differential direct injection pair includes NMOS-type transistors or PMOS-type transistors.
